(19) United States
(12) Patent Application Publication
(10) Pub. No.: US 2014/0287299 A1
(43) Pub. Date: Sep. 25, 2014

(54) Heat-Debonding Adhesives

(71) Applicant: APPLE INC., Cupertino, CA (US)

(72) Inventor: James R. Krogdahl, Cupertino, CA (US)

(73) Assignee: Apple Inc., Cupertino, CA (US)

(21) Appl. No.: 13/849,895

(22) Filed: Mar. 25, 2013

(51) Int. Cl. C09J 7/02; H05K 1/02; B32B 37/12; H01M 2/08; B32B 38/10

(52) U.S. Cl. CPC C09J 7/0246; H01M 2/08; B32B 38/10; B32B 37/12; H05K 1/02
USPC 429/185; 428/343; 428/317.3; 156/711; 156/60; 174/259

(57) ABSTRACT

A heat-debonding adhesive member is provided. The heat-debonding adhesive member attaches electronic device components such as a battery and a housing together. The heat-debonding adhesive includes a heat-generating layer that generates heat for debonding structures that are attached together using the adhesive member. The heat-generating layer includes a conductive layer that generates heat when a current flows through the conductive layer. The heat-debonding adhesive includes additional adhesive layers such as a voided polymer film having air-filled voids and one or more pressure-sensitive adhesive layers. A debonding tool provides current to conductive contacts on the conductive layer for generating heat in the heat-generating layer when it is desired to debond the structures that are attached together using the adhesive member.

### BACKGROUND

This relates generally to adhesives and, more particularly, to heat-debonding adhesives.

Adhesives are widely used to attach structures to each other. As an example, electronic devices such as computers and cellular telephones often contain adhesives for mounting components such as batteries and other display components to housing structures, for attaching housing structures to each other, and for otherwise assembling structures within a completed device.

In some situations, it can be desirable to remove and/or replace an electronic device component that has been attached within the device using adhesive. However, adhesives for attaching electronic device components are typically strong adhesives that are designed to maintain adhesion in a wide range of operating temperatures and operating conditions, including drop events. If care is not taken, adhesive-bonded device components can therefore be damaged or destroyed when removing the components.

It would therefore be desirable to be able to provide improved adhesives for attaching structures such as electronic device components.

### SUMMARY

An electronic device is provided with structures such as housing structures and electronic device structures associated with electrical components. Adhesives such as heat-debonding adhesives are used to attach these structures to each other.

The heat-debonding adhesive includes one or more adhesive layers and a heat-generating layer. The heat-generating layer includes conductive material that generates heat for debonding the adhesive. Heat generated in the heat-generating layer reduces the bonding strength of at least one of the adhesive layers.

The adhesive layers may include pressure sensitive adhesive layers, thermally cured adhesive layers, ultraviolet light curing adhesive layers, or other adhesive layers. The adhesive layers may include adhesive layers that are configured to debond and/or deform at high temperatures such as a voided polymer film. A voided polymer film may be formed from a polymer film having air-filled cavities.

The air-filled cavities that are located at a surface of the voided polymer film are configured to suction onto a surface of a structure to be bonded or onto other adhesive layers in the adhesive. When heated, the air-filled cavities expand, causing the voided polymer film to warp. The warped film may cause other adhesive layers to debond from a surface.

The heat-generating layer includes one or more conductive contacts. Currents such as electrically driven currents can be provided to the heat-generating layer through the electrical contacts to induce heating in the heat-generating layer that debonds the adhesive. Magnetically induced currents may also generate heat in the heat-generating layer.

Further features, their nature and various advantages will be more apparent from the accompanying drawings and the following detailed description of the preferred embodiments.

### BRIEF DESCRIPTION OF THE DRAWINGS

FIG. 1 is a perspective view of an illustrative electronic device such as a laptop computer with structures that are attached to each other with heat-debonding adhesive in accordance with an embodiment.

FIG. 2 is a perspective view of an illustrative electronic device such as a handheld electronic device with structures that are attached to each other with heat-debonding adhesive in accordance with an embodiment.

FIG. 3 is a perspective view of an illustrative electronic device such as a tablet computer with structures that are attached to each other with heat-debonding adhesive in accordance with an embodiment.

FIG. 4 is a perspective view of an illustrative electronic device such as a computer display with structures that are attached to each other with heat-debonding adhesive in accordance with an embodiment.

FIG. 5 is a perspective view of an illustrative electronic device showing how the device may include heat-debonding adhesive that attaches device components to housing structures and other device components in accordance with an embodiment.

FIG. 6 is a perspective view of a portion of an illustrative head-debonding adhesive with conductive contacts on a heat-generating layer in accordance with an embodiment.

FIGS. 7A and 7B are perspective views of a structure that is bonded to a heat-debonding adhesive showing how the heat-debonding adhesive is debonded from the structure in accordance with an embodiment.

FIG. 8 is a perspective of an illustrative electronic device having a battery that is attached to a housing of the device in accordance with an embodiment.

FIG. 9 is a perspective of an illustrative electronic device having a display that is attached to a housing of the device in accordance with an embodiment.

FIG. 10 is a cross-sectional side view of a portion of an illustrative head-debonding adhesive with a heat-debonding layer and a heat-generating layer in accordance with an embodiment.

FIG. 11 is a cross-sectional side view of a portion of an illustrative head-debonding adhesive with multiple heat-debonding layers and a heat-generating layer in accordance with an embodiment.

FIG. 12 is a cross-sectional side view of a portion of an illustrative heat-debonding adhesive with conductive contacts formed from openings in a pressure-sensitive adhesive layer and a heat-debonding layer in accordance with an embodiment.

FIG. 13 is a cross-sectional side view of a portion of an illustrative heat-debonding adhesive with conductive contacts formed from openings in a pressure-sensitive adhesive layer and an insulating layer in accordance with an embodiment.

FIG. 14 is a cross-sectional side view of a portion of an illustrative heat-debonding adhesive with a heat-debonding layer that extends from an edge of the heat-debonding adhesive in accordance with an embodiment.

FIG. 15 is a cross-sectional side view of a portion of an illustrative heat-debonding adhesive showing how heat from a heat-generating layer may cause voids in a heat-debonding layer to expand in accordance with an embodiment.

FIG. 16 is a perspective view of a portion of an illustrative heat-generating layer of a heat-debonding adhesive having conductive traces on a carrier layer in accordance with an embodiment.

FIG. 17 is a perspective view of a portion of an illustrative heat-generating layer of a heat-debonding adhesive having a conductive sheet on a carrier layer in accordance with an embodiment.

FIG. 18 is a cross-sectional side view of a portion of an illustrative heat-debonding adhesive having thin wires interposed between a heat-debonding layer and a carrier layer in accordance with an embodiment.

FIG. 19 is a cross-sectional side view of a portion of an illustrative heat-debonding adhesive having a conductive sheet attached to a thin pressure-sensitive adhesive layer in accordance with an embodiment.

FIG. 20 is an illustrative diagram showing how a conductive sheet of the type shown in FIG. 19 may be attached to adhesive structures having a heat-debonding layer in accordance with an embodiment.

FIG. 21 is an illustrative diagram showing how a conductive sheet of the type shown in FIG. 19 may be patterned using a laser in accordance with an embodiment.

FIG. 22 is a flow chart of illustrative steps involved in attaching structures together using a heat-debonding adhesive in accordance with an embodiment.

FIG. 23 is a flow chart of illustrative steps involved in debonding structures that are attached together using a heat-debonding adhesive in accordance with an embodiment.

### DETAILED DESCRIPTION

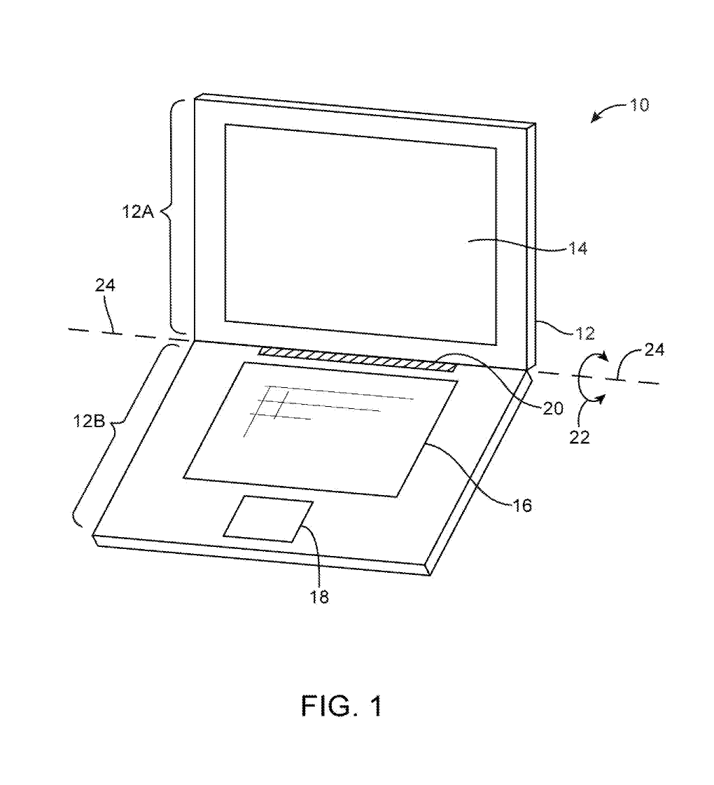

Illustrative electronic devices that have heat-debonding adhesives are shown in FIGS. 1, 2, 3, and 4.

Electronic device 10 of FIG. 1 has the shape of a laptop computer and has upper housing 12A and lower housing 12B with components such as keyboard 16 and touchpad 18. Device 10 has hinge structures 20 (sometimes referred to as a clutch barrel) to allow upper housing 12A to rotate in directions 22 about rotational axis 24 relative to lower housing 12B. Display 14 is mounted in upper housing 12A. Upper housing 12A, which may sometimes referred to as a display housing or lid, is placed in a closed position by rotating upper housing 12A towards lower housing 12B about rotational axis 24.

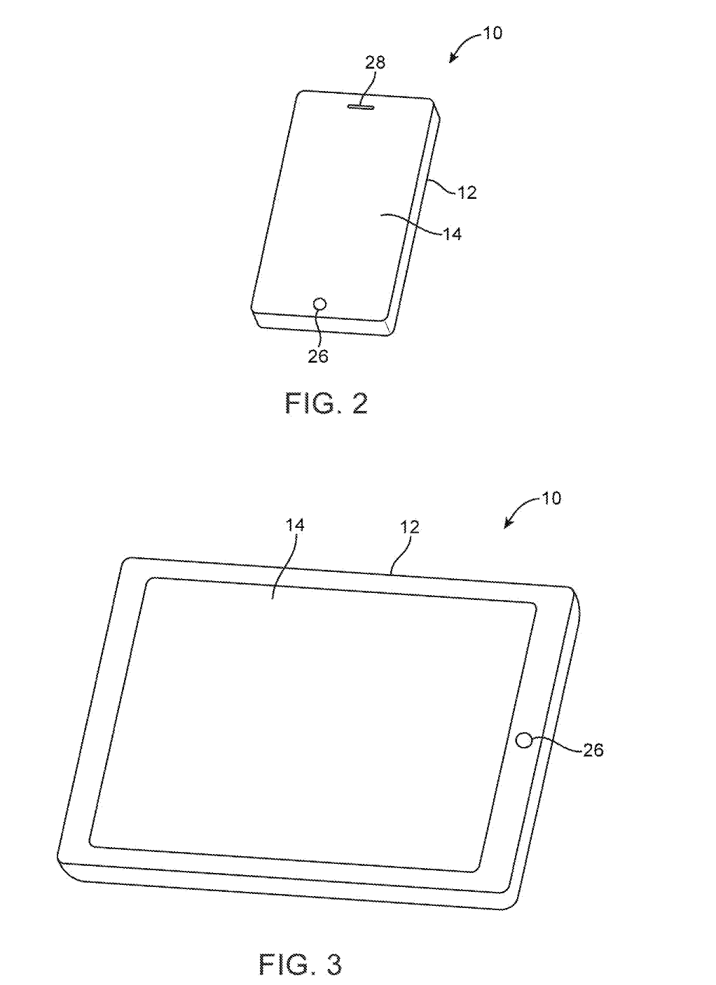

FIG. 2 shows an illustrative configuration for electronic device 10 based on a handheld device such as a cellular telephone, music player, gaming device, navigation unit, or other compact device. In this type of configuration for device 10, housing 12 has opposing front and rear surfaces. Display 14 is mounted on a front face of housing 12. Display 14 may have an exterior layer that includes openings for components such as button 26 and speaker port 28.

In the example of FIG. 3, electronic device 10 is a tablet computer. In electronic device 10 of FIG. 3, housing 12 has opposing planar front and rear surfaces. Display 14 is mounted on the front surface of housing 12. As shown in FIG. 3, display 14 has an external layer with an opening to accommodate button 26.

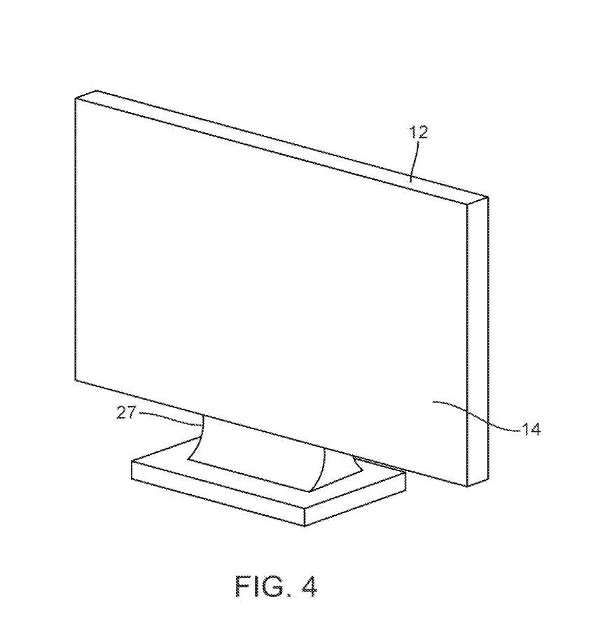

FIG. 4 shows an illustrative configuration for electronic device 10 in which device 10 is a computer display or a computer that has been integrated into a computer display. With this type of arrangement, housing 12 for device 10 is mounted on a support structure such as stand 27. Display 14 is mounted on a front face of housing 12.

The electrical devices of FIGS. 1, 2, 3, and 4 include heat-debonding adhesives that attach one or more device structures to other device structures or components within the device. The illustrative configurations for device 10 that are shown in FIGS. 1, 2, 3, and 4 are merely illustrative. In general, electronic device 10 may be a laptop computer, a computer monitor containing an embedded computer, a tablet computer, a cellular telephone, a media player, or other handheld or portable electronic device, a smaller device such as a wrist-watch device, a pendant device, a headphone or earpiece device, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment.

Housing 12 of device 10, which is sometimes referred to as a case, is formed of materials such as plastic, glass, ceramics, carbon-fiber composites and other fiber-based composites, metal (e.g., machined aluminum, stainless steel, or other metals), other materials, or a combination of these materials. Device 10 may be formed using a unibody construction in which most or all of housing 12 is formed from a single structural element (e.g., a piece of machined metal or a piece of molded plastic) or may be formed from multiple housing structures (e.g., outer housing structures that have been mounted to internal frame elements or other internal housing structures).

Display 14 may be a touch sensitive display that includes a touch sensor or may be insensitive to touch. Touch sensors for display 14 may be formed from an array of capacitive touch sensor electrodes, a resistive touch array, touch sensor structures based on acoustic touch, optical touch, or force-based touch technologies, or other suitable touch sensor components.

Display 14 for device 10 includes display pixels formed from liquid crystal display (LCD) components or other suitable image pixel structures.

A display cover layer may cover the surface of display 14 or a display layer such as a color filter layer or other portion of a display may be used as the outermost (or nearly outermost) layer in display 14. The outermost display layer may be formed from a transparent glass sheet, a clear plastic layer, or other transparent member.

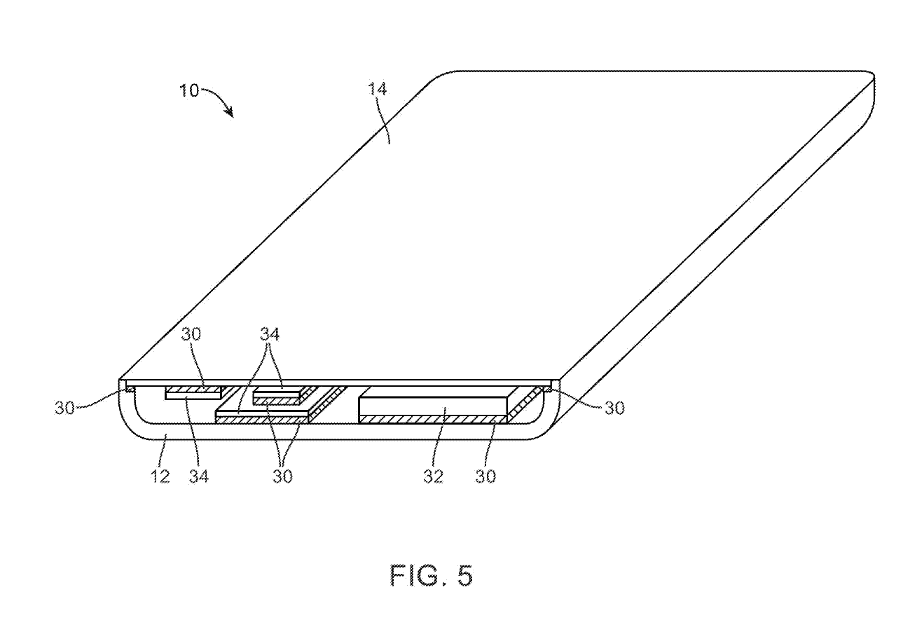

FIG. 5 is a perspective view of device 10 (e.g., device 10 of FIG. 1, 2, 3 or 4, or any other suitable electronic device) showing how components within the device may be attached to other components, to housing 12, or to display 14. In the example of FIG. 5, device 10 includes a battery 32 that is attached to housing 12. Heat-debonding adhesive member 30 attaches battery 32 to housing 12. Heat-debonding adhesive members 30 also attach other components such as components 34 within device 10. Components 34 may be electronic components such as printed circuit boards, integrated circuits, a compass, a speaker, a microphone, a vibrator, a structural support member, or any other electronic device components.

Heat-debonding adhesive members 30 may attach components 34 to housing 12, to display 14, to other components 34, or to internal support structures within device 10.

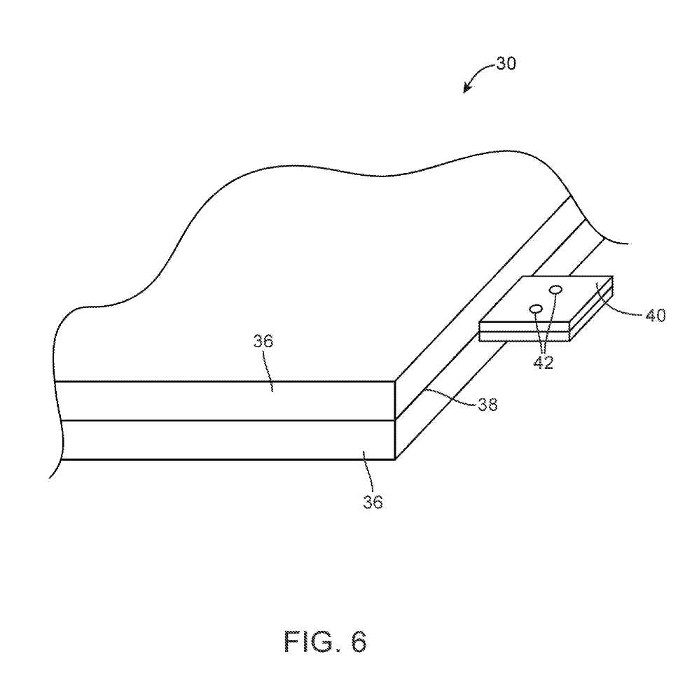

FIG. 6 is a perspective view of a portion of a heat-debonding adhesive such as heat debonding adhesive members 30 of FIG. 6. In the example of FIG. 6, heat-debonding adhesive member 30 includes a layer for generating heat such as heat-generating layer 38. Adhesive member 30 also includes additional adhesive layers 36. Adhesive member 30 may include one or more additional adhesive layers 36 each side of heat-generating layer 38. Additional adhesive layers 36 may include one or more pressure sensitive adhesive layers, one or more thermo-plastic adhesives, one or more other adhesive layers that are configured to debond and/or deform when exposed to high temperatures, one or more insulating layers, or other suitable adhesive layers.

Adhesive layers 36 may include adhesive layers that maintain adhesive bonds at normal operating temperatures for device 10 and that debond at relatively high temperatures (e.g., temperatures of over 120 degrees Celsius, temperatures of over 150 degrees Celsius, etc.). As examples, layers 36 may include a pressure-sensitive adhesive layer that is softened and/or damaged at relatively high temperatures, a thermo-plastic adhesive that melts at relatively high temperatures, a voided polymer film with air-filled cavities that expand and debond at relatively high temperatures, or other heat-debonding adhesive layers. Heat-generating layer 38 may include a conductive layer such as a thermally conductive layer or an electrically conductive layer formed on an insulating layer.

Heat-debonding adhesive member 30 of FIG. 6 includes an extended portion 40 having conductive contacts 42. Conductive contacts 42 may be exposed portions of a conductive layer of heat-generating layer 38. An electrical current may be applied to conductive contacts 42. The applied electrical current may generate currents within heat-generating layer 38 that generate heat within heat-generating layer 38. The heat generated within layer 38 may cause a heat-debonding layer of layers 36 to debond from a surface of a structure or may cause other adhesive layers within layers 36 to warp and/or deform, thereby causing those layers to debond from a surface of a structure.

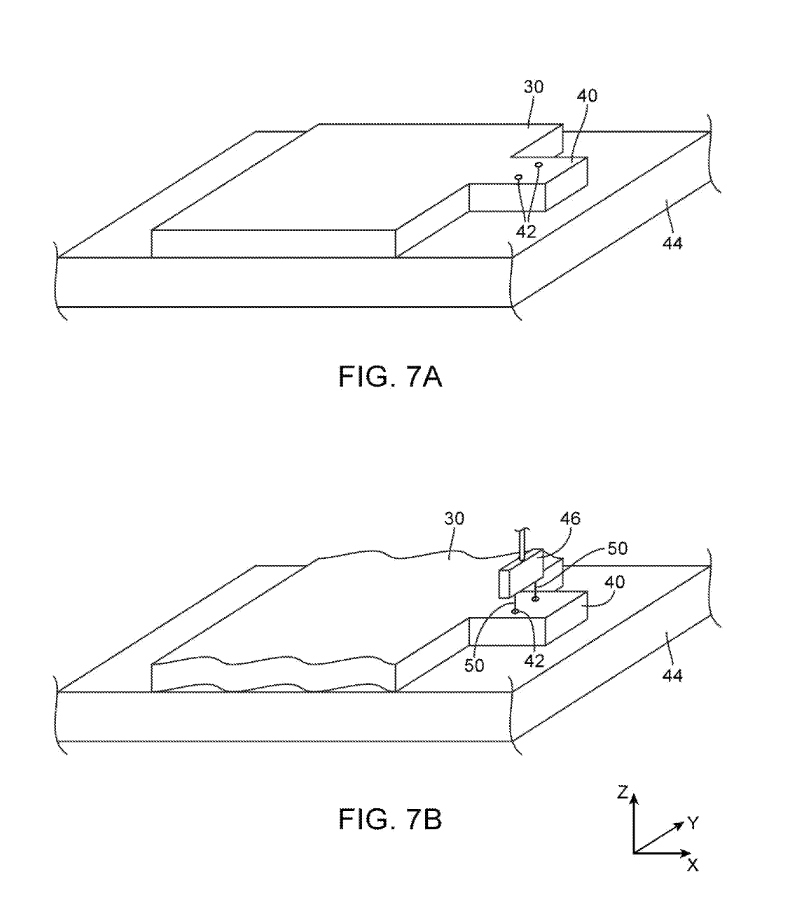

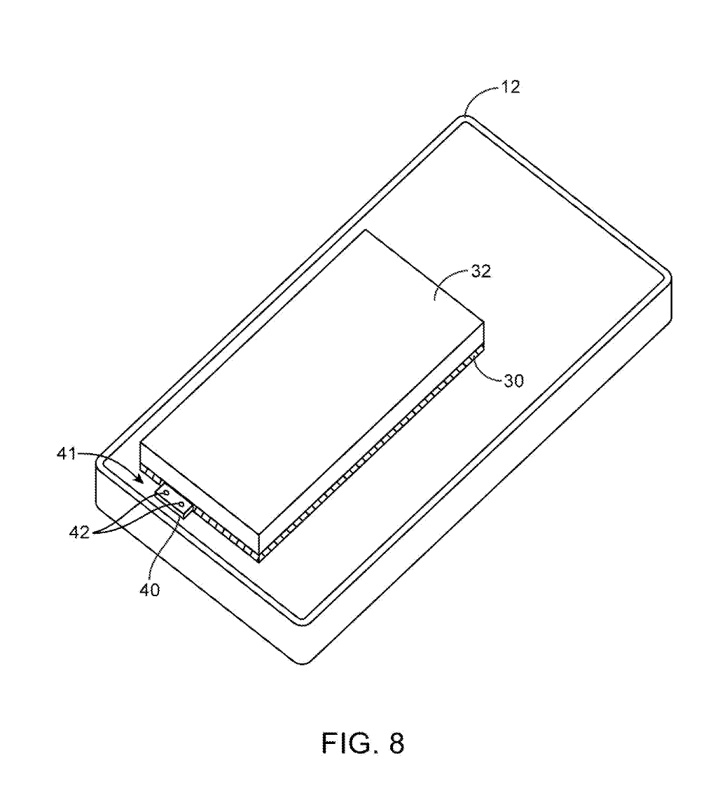

FIGS. 7A and 7B show how heat-debonding adhesive member 30 may be debonded from a structure to which it is attached by applying a current to contacts 42.

In the example of FIG. 7A, a surface of heat-debonding adhesive 30 is attached to structure 44 (e.g., an electronic device battery such as battery 32, an electronic device housing such as housing 12, an electronic device display such as display 14, etc.). Another structure may be attached to an opposing surface of adhesive 30, though no additional structure is shown in FIG. 7A for illustrative purposes.

In the example of FIG. 7B, a tool such as debonding tool 46 can be used to provide a heat-generating current to heat-generating layer 38. Debonding tool 46 may include conductive probes 50. Probes 50 may be configured to deliver a current such as an electrical current to conductive material in heat-generating layer 38. Heat-generating layer 38 generates heat in response to the electrical current from tool 46. Heat may be generated in layer 38 through resistive heating, inductive heating, or by transferring heat directly to heat-generating layer by conduction.

In order to avoid damage to structure 44, heat is generated quickly within adhesive member 30 so that adhesive member 30 debonds from structure 44 before damaging amounts of heat penetrate insulating layers of adhesive member 30 (e.g., insulating polymer layers or insulating adhesive layers such as pressure-sensitive adhesive layers).

The heat generated in layer 38 conductively heats other layers such as adhesive layers 36 (see FIG. 6) of adhesive member 30. The heat that passes into adhesive layers 36 causes adhesive 30 to debond from structure 44. In the example of FIG. 7B, when a current is supplied to contacts 42, heat that is generated in heat-generating layer 38 causes adhesive member 30 to deform or to warp.

The deformation of member 30 generates pulling forces that lift portions of member 30 at an acute angle with respect to the surface of structure 44 (e.g., forces in a direction between the x-y plane and the z-direction of FIG. 7B). The bonding strength of adhesive member 30 may be stronger in the direction perpendicular to the surface of structure 44 and in the direction parallel to the surface of structure 44 than in directions at acute angles with respect to the surface of structure 44. Pulling forces at an acute angle of pull that are generated by the warping of member 30 therefore relatively easily debond member 30 from structure 44 while maintaining the bonding strength of adhesive 30 under normal operation conditions of device 10.

In situations in which adhesive 30 is used to attach an electronic device component to an electronic device housing, extended portion 40 of member 30 may extend from a space between the component and the housing so that contacts 42 are accessible for debonding of adhesive 30.

In the example of FIG. 8, battery 32 is attached to housing 12 using a heat-debonding adhesive such as adhesive 30. Extended portion 40 extends from underneath battery 32 within gap 41 between battery 32 and housing 12. When it is desired to debond battery 32 from housing 12, a debonding tool such as tool 46 is inserted into gap 41 so that probes 50 provide current to contacts 42, thereby debonding battery 32 from housing 12 without damaging battery 32 or housing 12.

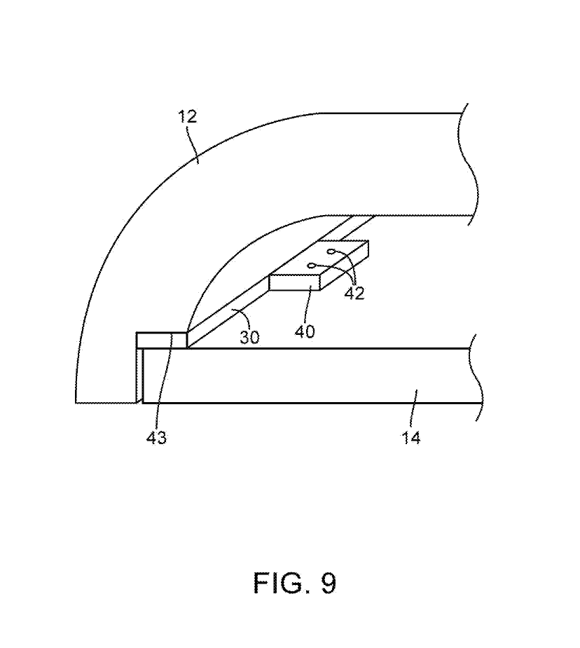

In the example of FIG. 9, display 14 is attached to ledge 43 of housing 12 using heat-debonding adhesive 30. In this type of configuration, adhesive 30 may extend around some or all of the periphery of device 10 on ledge 43. Extended portion 40 extends from between display 14 and housing 12. When it is desired to debond display 14 from housing 12, a debonding tool such as tool 46 is inserted into a space between display 14 and housing 12 so that probes 50 provide current to contacts 42, thereby debonding display 14 from housing 12 without damaging display 14 or housing 12.

The examples of FIGS. 8 and 9 are merely illustrative. In general, heat-debonding adhesive 30 may be used to attach any type of structures together and heat that is generated in heat-generating layer 38 may debond adhesive 30 from any type of structure.

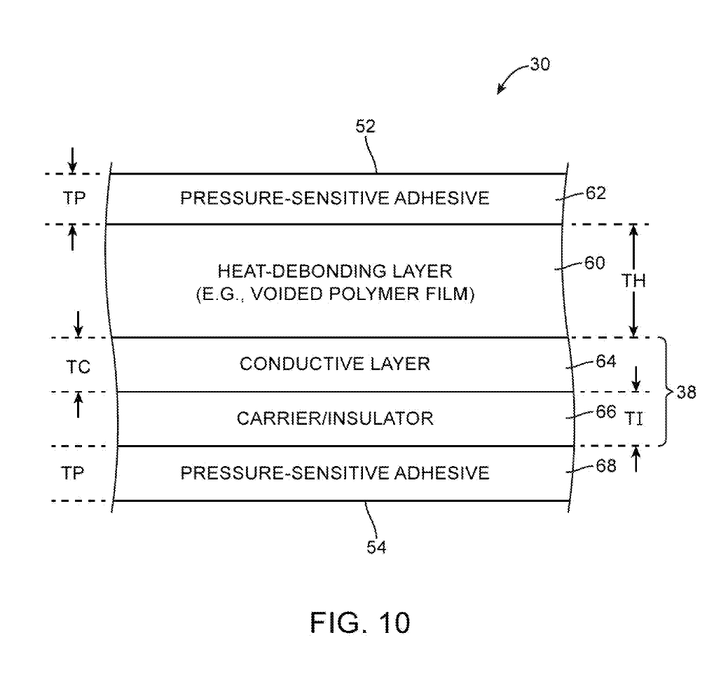

FIG. 10 shows one suitable configuration for heat-debonding adhesive member 30. In the example of FIG. 10, heat-generating layer 38 includes conductive layer 64. Conductive layer may be a thermally conductive layer, an electrically conductive layer, a thermally and electrically conductive layer, etc. Conductive layer 64 is formed on an insulating layer such as layer 66. Layer 66 may be formed from electrically and/or thermally insulating material such as a polymer material.

When electrically driven and/or magnetically induced currents flow within conductive layer 64, heat is generated in conductive layer 64.

Conductive layer 64 is attached to a heat-debonding adhesive layer such as heat-debonding layer 60.

Heat-debonding layer 60 may be formed from a material that holds an adhesive bond at the normal operating temperatures of device 10 (e.g., up to 100 degrees Celsius) and that warps and/or debonds at higher temperatures. As examples, heat-debonding layer 60 may debond and/or warp at temperatures between 120 C and 150 C, between 120 C and 130 C, between 140 C and 150 C, greater than 120 C, greater than 140 C, or greater than 150 C.

In one suitable configuration that is sometimes discussed herein as an example, heat-debonding adhesive 60 is formed from a voided polymer film. A voided polymer film is a thin polymer sheet having openings such as air bubbles in the polymer sheet. Air bubbles at the surface of the polymer sheet form suction bonds with surfaces that contact the air bubbles. When heat is applied to layer 60 (e.g., from layer 38) the voids (e.g., the air bubbles) expand, thereby deforming and/or debonding layer 60.

In the example of FIG. 10, adhesive member 30 includes a first pressure-sensitive adhesive (PSA) layer 62 attached to heat-debonding layer 60 and a second pressure-sensitive adhesive layer 68 attached to insulating/carrier layer 66. Adhesive 30 may be used to attach structures to each other by pressing a first structure (e.g., a device battery or a device display) against surface 52 of PSA 62 and pressing a second structure (e.g., a device housing) against opposing surface 54 of PSA 68.

PSA 62 and PSA 68 may be configured to bond to a specific type of surface (e.g., the surface of a battery or the surface of an aluminum housing) or may be general pressure-sensitive adhesives that bond to a variety of surfaces.

Each of PSA layers 62 and 68 may be configured to form a bond with an attached structure that holds during normal operation of device 10 (e.g., at normal operating temperatures for device 10 such as operating temperatures that occur in a users hand or in a hot car) and during drop events (e.g., when a user drops device 10).

One or both of PSA layers 62 and 68 may deform as described above in connection with FIG. 7B in response to changes (e.g., deformations or warps) in heat-debonding layer 60 when heat is generated in heat-generating layer 38. In this way, deformations in layers 62 and/or 68 may debond adhesive member 30 from structures that are attached to surface 52 and/or surface 54.

The layers of adhesive member may each have a characteristic thickness. As examples, pressure-sensitive adhesive layers 62 and 68 may each have a thickness TP that is between 5 microns and 10 microns, between 9 microns and 11 microns, between 5 microns and 20 microns, greater than 5 microns, less than 15 microns, or less than 10 microns. As examples, heat-debonding layer 60 may have a thickness TH that is between 45 microns and 55 microns, between 40 microns and 60 microns, between 30 microns and 85 microns, greater than 30 microns, less than 60 microns, or less than 50 microns. As examples, conductive layer 64 may have a thickness TC that is between 5 microns and 10 microns, between 9 microns and 11 microns, between 5 microns and 20 microns, greater than 5 microns, less than 15 microns, or less than 10 microns. As examples, carrier/insulator layer 66 may have a thickness TI that is between 5 microns and 10 microns, between 9 microns and 11 microns, between 5 microns and 20 microns, greater than 5 microns, less than 15 microns, or less than 10 microns.

Thicknesses TP, TH, TC, and TI may be chosen so that the total thickness of adhesive member 30 (e.g., the sum of thicknesses TP, TH, TC, and TI) is between 75 microns and 80 microns, between 70 microns and 90 microns, less than 100 microns, less than 90 microns, less than 80 microns, or less than 75 microns (as examples).

The configuration of adhesive member 30 of FIG. 10 is merely illustrative. Other configurations may be used.

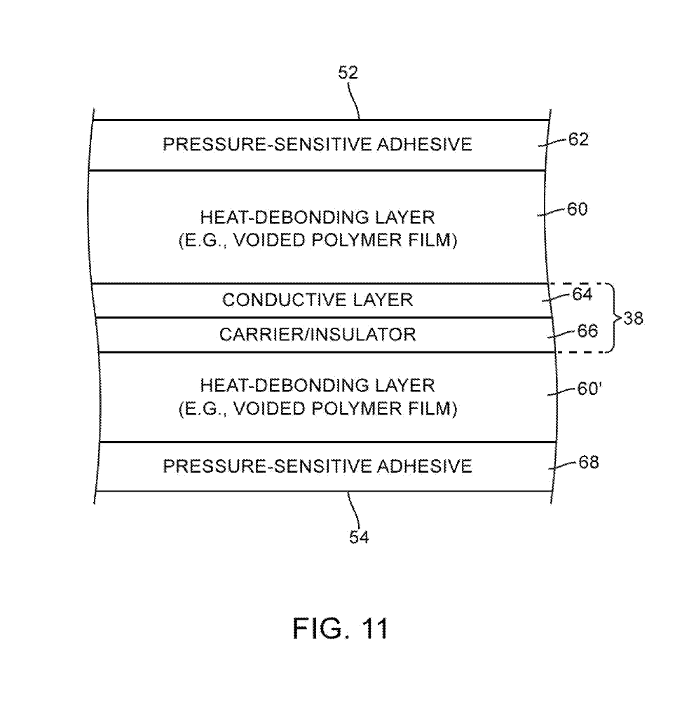

In the example of FIG. 11, adhesive member 30 is provided with an additional heat-debonding layer 60′. Heat-debonding layer 60′ is attached to carrier/insulator layer 66 of heat-generating layer 38. When heat is generated in conductive layer 64 of layer 38, changes (e.g., expanding voids in a polymer film) in layers 60 and 60′ cause warping of PSA layer 62 and 68 that debond adhesive member 30 from structures that are bonded to surfaces 52 and/or 54.

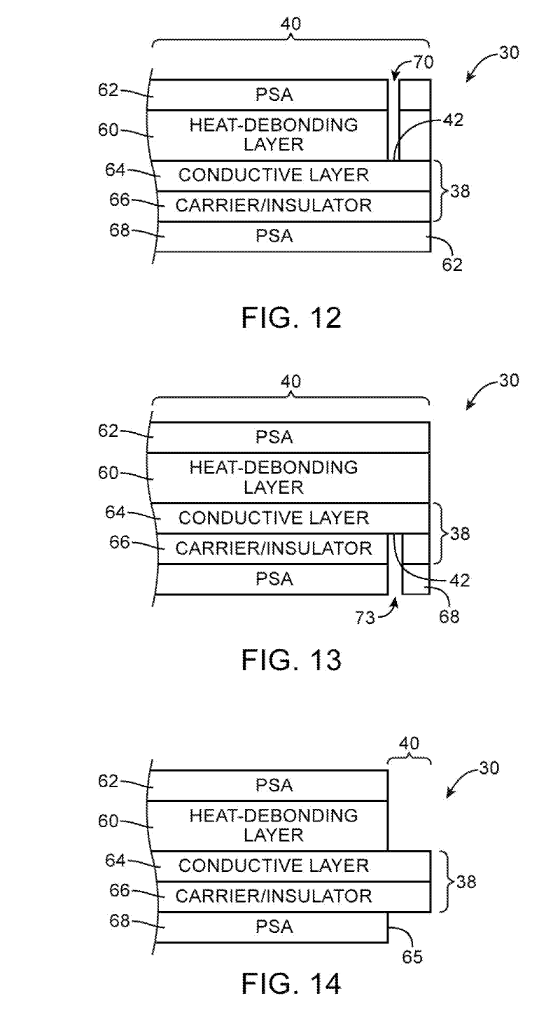

FIG. 12 is a cross-sectional view of a part of extended portion 40 of adhesive member 30 showing how contacts 42 may be formed from an opening in pressure-sensitive adhesive layer 62 and heat-debonding layer 60. Openings such as opening 70 expose part of conductive layer 64 to form contacts 42. Probes 50 of tool 46 (see FIG. 7B) may be inserted into openings such as opening 70 in order supply a current to conductive layer 64.

FIG. 13 is a cross-sectional view of a part of extended portion 40 of adhesive member 30 showing how contacts 42 may be formed from an opening in pressure-sensitive adhesive layer 68 and insulating/carrier layer 66. Openings such as opening 73 expose part of conductive layer 64 to form contacts 42. Probes 50 of tool 46 (see FIG. 7B) may be inserted into openings such as opening 73 in order supply a current to conductive layer 64.

The configurations of extended portion 40 shown in FIGS. 12 and 13 are merely illustrative. If desired, extended portion 40 may be formed from a portion of heat-generating layer 38 that extends from an edge of adhesive member 30 as shown in FIG. 14. In the example of FIG. 14, layers 66 and 64 of heat-generating layer 38 extend beyond edge 65 of adhesive member 30 (e.g., an edge formed from aligned edges of layers 62, 60 and 68). An extended portion 40 of this type may run along some or all of edge 65 of member 30. If desired, member 30 may be provided with multiple extended portions 40 along multiple edges.

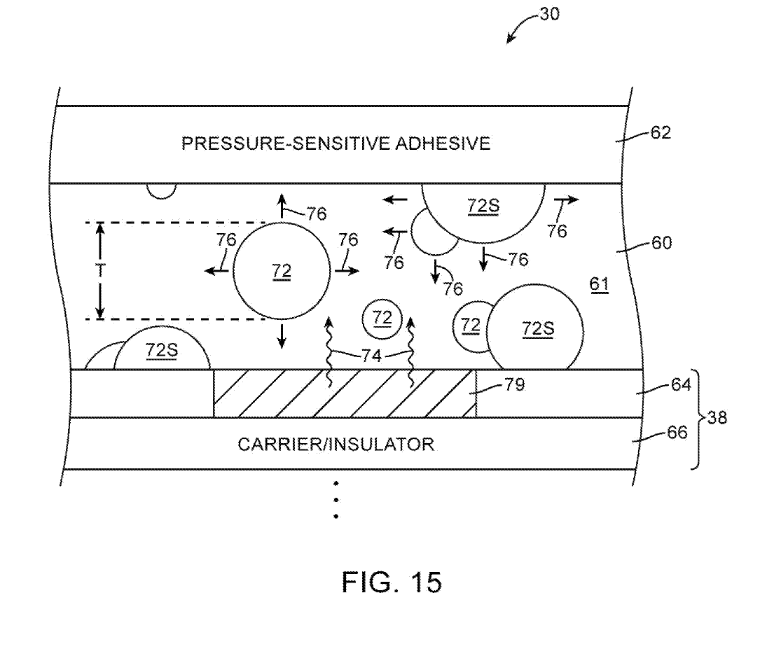

FIG. 15 is a cross-sectional view of a portion of adhesive member 30 showing how heat-debonding layer 60 may be formed from a voided polymer film. In the example of FIG. 15, layer 60 is formed from polymer material 61 (e.g., a polymer blend, a polymer alloy, or other polymer material) with voids 72. Voids 72 are air-filled cavities or cavities filled with other gasses within material 61. Voids 72 have a characteristic thickness T. Thickness T may be between 1 mm and 3 mm, between 0.5 mm and 5 mm, between 0.1 mm and 0.9 mm, smaller than 1 mm, smaller than 3 mm, larger than 0.01 mm or between 1 mm and 5 mm (as examples).

Voids 72S that are formed at the outer surfaces of layer 60 may adhere to a material that contacts those outer surfaces by suctioning onto the material.

As shown in FIG. 15, when heat 74 from a conductive element such as element 79 of conductive layer 64 enters layer 60, some or all of voids 72 expand (as indicated by arrows 76). This expansion of voids 72 (and 72S) in response to heat 74 may warp, debond, or even destroy layer 60. The warping of layer 60 causes other adhesive layers such as PSA layers 62 and/or 68 to warp and or bend as described in connection with FIG. 7B, thereby debonding PSA layers 62 and/or 68 from a surface to which they are bonded.

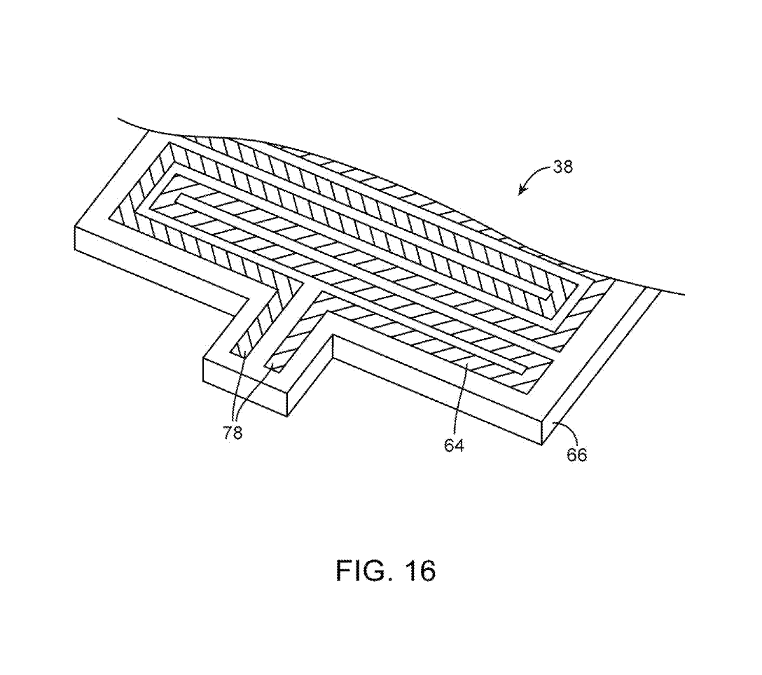

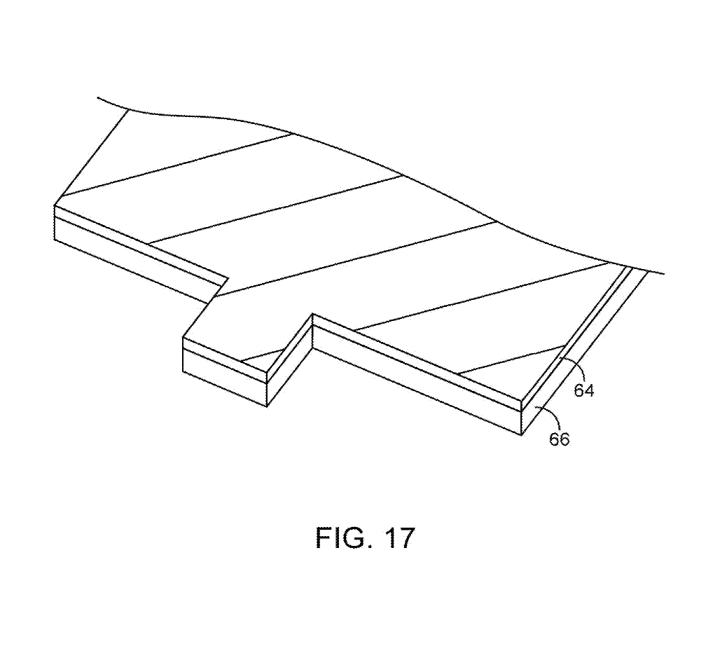

FIG. 16 is a perspective view of a portion of heat-generating layer 38 showing how conductive layer 64 may be formed from metal traces 78 on carrier/insulator layer 66. Traces 78 may be formed from conductive material such as copper or aluminum. In the example of FIG. 16, traces 78 are etched metal traces that form a meandering path on layer 66. Resistance to current flowing through traces 78 generates heat that passes into one or more adhesive layers such as a heat-debonding layer of adhesive member 30. However, the meandering traces of FIG. 16 are merely illustrative. If desired, conductive layer 64 may be formed in other configurations such as in a continuous conductive sheet as shown in FIG. 17.

In the example of FIG. 17, conductive layer 64 is a continuous sheet of conductive material (e.g., metal, copper, aluminum, or other suitable conductive material) that covers substantially all of layer 66. In this type of configuration, heat can be generated in layer 64, for example, by inducing eddy currents within sheet 64 (e.g., by applying magnetic fields to sheet 64). A conductive sheet of the type shown in FIG. 17 may have a thickness that is less than the thickness of traces 78 of FIG. 16. For example the thickness of sheet 64 of FIG. 17 may be between 3 microns and 7 microns, between 1 microns and 10 microns, less than 10 microns, less than 7 microns, or less than 5 microns (as examples).

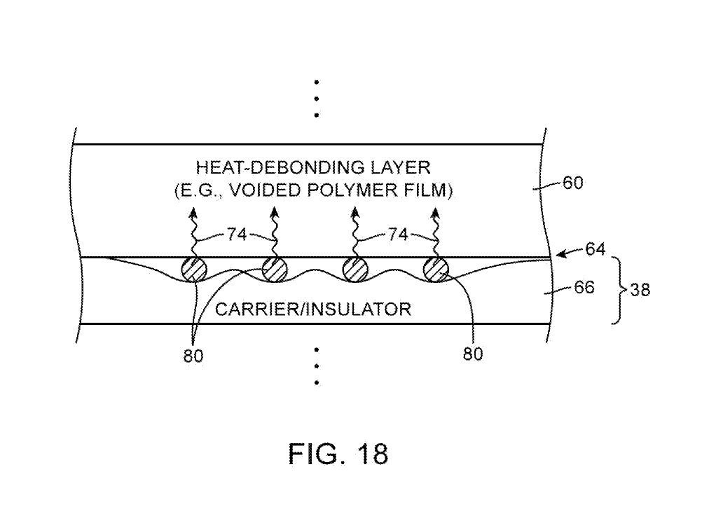

FIG. 18 is a cross-sectional view of a portion of adhesive member 30 showing how conductive layer 64 of heat-generating layer 38 may be formed from thin wires 80 that run between carrier/insulator layer 66 and heat-debonding layer 60. Wires 80 are coupled to contacts 42 (see, e.g., FIG. 7A) so that currents that pass through wires 80 generate heat 74 that passes into one or more heat-debonding layers. In this type of configuration, layer 66 may hold wires 80 in place against heat-debonding layer 60.

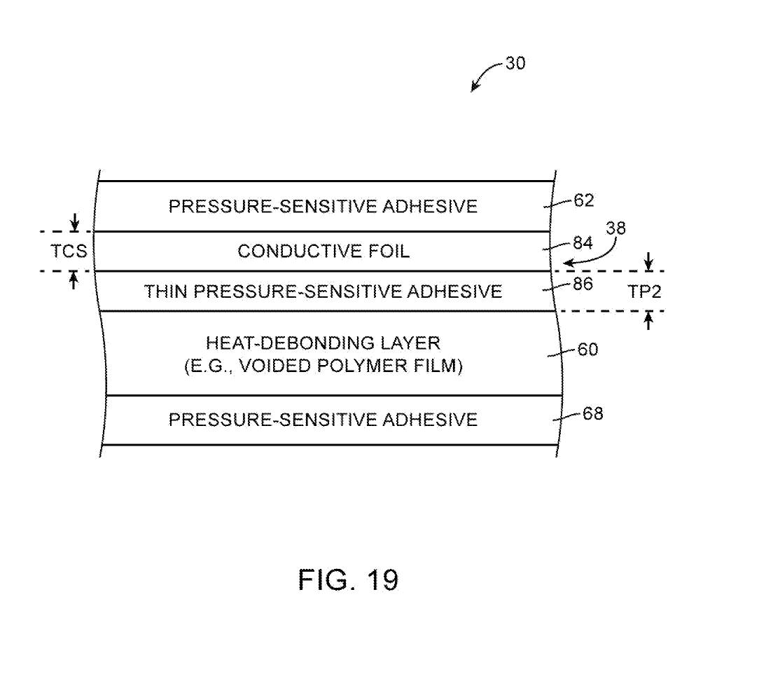

In some configurations, heat-generating layer 38 may be formed from a conductive layer such as a thin conductive foil that is provided without an insulating carrier layer as shown in FIG. 19.

In the example of FIG. 19, conductive foil 84 is formed from a thin conductive sheet having a thickness TCS. Conductive foil 84 is interposed between pressure-sensitive adhesive layer 62 and an additional pressure-sensitive adhesive layer 86. Conductive foil 84 may be formed from metal such as copper or aluminum. Layer 86 may have a thickness TP2 that is smaller than thickness TP of layers 62 and/or 68 so that heat generated in foil 84 can pass through layer 86 into heat-debonding layer 60. Thickness TCS of conductive foil 84 may be, as examples, between 3 microns and 7 microns, between 1 micron and 10 microns, less than 10 microns, less than 7 microns, or less than 5 microns. Thickness TP2 of layer 86 may be, as examples, between 4 microns and 7 microns, between 3 microns and 10 microns, less than 10 microns, less than 7 microns, or less than 5 microns.

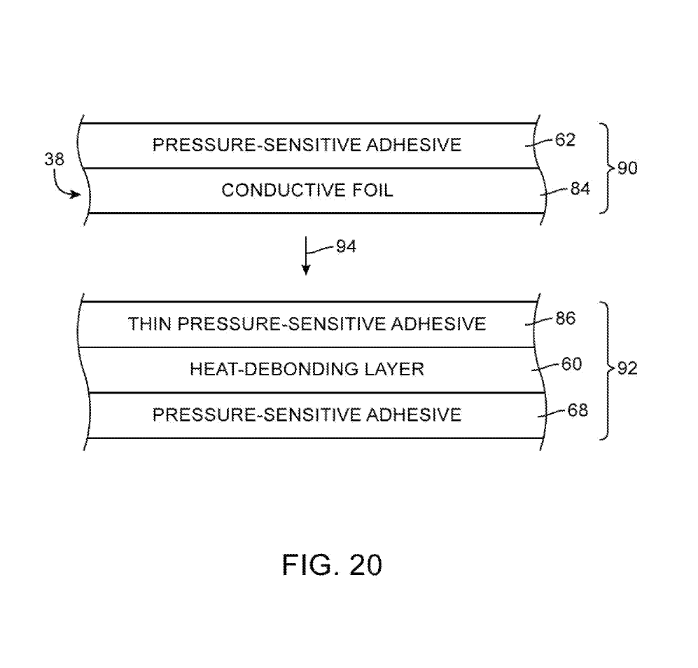

FIG. 20 is a diagram showing how adhesive member 30 of FIG. 19 may be formed from a first adhesive component 90 and a second adhesive component 92. In the example of FIG. 20, component 90 includes pressure sensitive adhesive layer 62 attached to conductive foil 84. Component 92 includes heat-debonding layer 60. Pressure-sensitive adhesive layer 68 is attached to one side of heat-debonding layer 60 and thin pressure-sensitive adhesive layer 86 is attached to an opposing side of layer 60.

If desired, member 90 may be manufactured separately from member 90. In this type of situation, member 90 is attached to member 92 as indicated by arrow 94 to form a heat-debonding adhesive member such as heat-debonding adhesive member 30 of FIG. 19. By pressing conductive foil 84 against layer 86, member 90 is bonded to member 92.

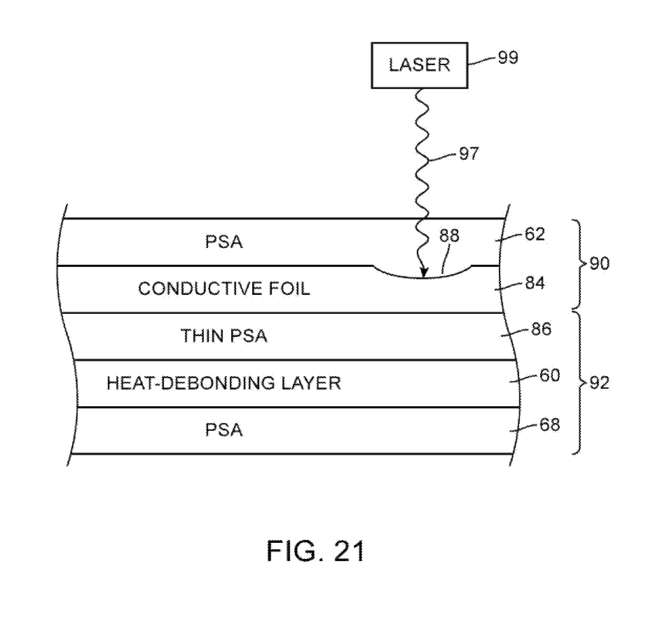

If desired, conductive foil 84 may be a patterned conductive foil layer. Foil 84 may be etched or otherwise patterned before being attached to member 92 or after attachment to member 92. For example, as shown in FIG. 21, laser light may be used to etch a pattern into foil 84. In the example of FIG. 21, laser 99 generates laser light 97. Laser light 97 has a wavelength that is chosen so that laser light 97 passes through PSA layer 62 and is absorbed by foil 84 so that patterned structures such as opening 88 are formed in foil 84. Openings such as opening 88 may pass completely or partially through foil 84 and may form any desired pattern in foil 84. Patterned openings 88 in foil 84 may enhance the heat that is generated in foil 84 when currents are applied to foil 84 (e.g., through conductive contacts such as contacts 42 of FIG. 6).

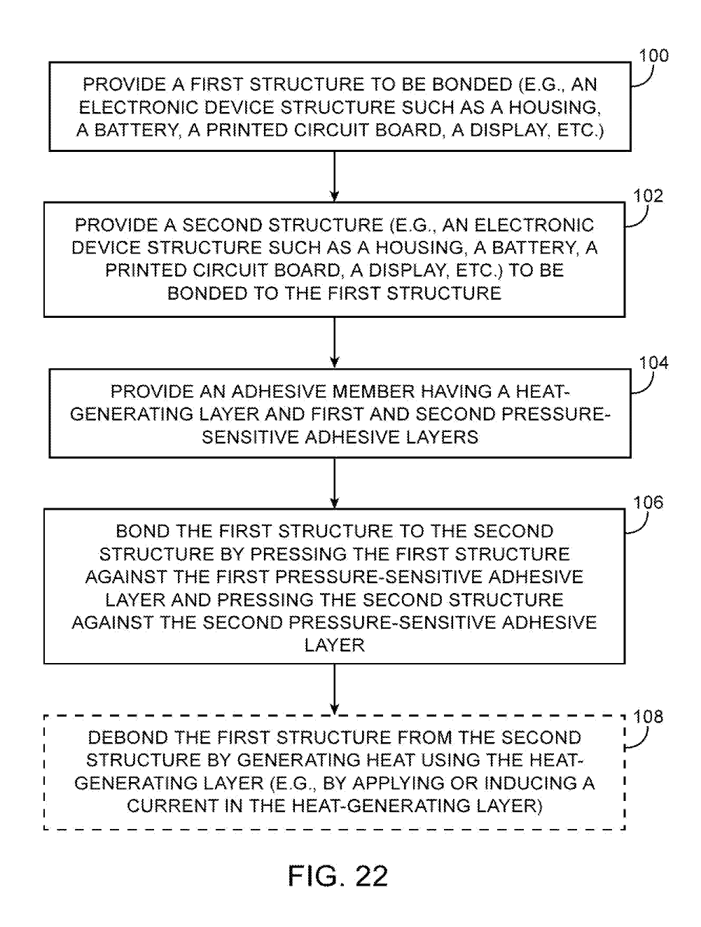

Illustrative steps that may be used in attaching structures together using a heat-debonding adhesive member such as heat-debonding adhesive member 30 are shown in FIG. 22.

At step 100, a first structure to be attached (bonded) is provided. The first structure may be an electronic device structure such as a housing, a battery, a printed circuit board, a display, another electronic device structure or any other suitable structure.

At step 102, a second structure to be attached (bonded) to the first structure is provided. The first structure may be an electronic device structure such as a housing, a battery, a printed circuit board, a display, another electronic device structure or any other suitable structure.

At step 104, an adhesive member such as a heat-debonding adhesive member having a heat-generating layer and first and second pressure-sensitive adhesive layers is provided. The provided adhesive member may include additional layers such as a heat-debonding layer of the type that is included in heat-debonding adhesive member 30 of FIGS. 5, 6, 7A, 8, 9, 10, 11, 12, 13, 14, 15, 16, 17, 18, 19, 21 (as examples).

At step 106, the first structure is attached (bonded) to the second structure by pressing the first structure against the first pressure-sensitive adhesive layer and pressing the second structure against the second pressure-sensitive adhesive layer.

If it is desired to detach the first structure from the second structure, at optional step 108, the first structure is detached (debonded) from the second structure by generating heat using the heat-generating layer of the provided adhesive member. The heat may be generated by applying or inducing a current in a conductive layer of the heat-generating layer. The generated heat may cause changes in a heat-debonding layer of the adhesive member that detach the adhesive member from one or both of the first and second structures. For example, the generated heat may expand air bubbles in a voided polymer layer that cause the adhesive member to deform and debond from the structures.

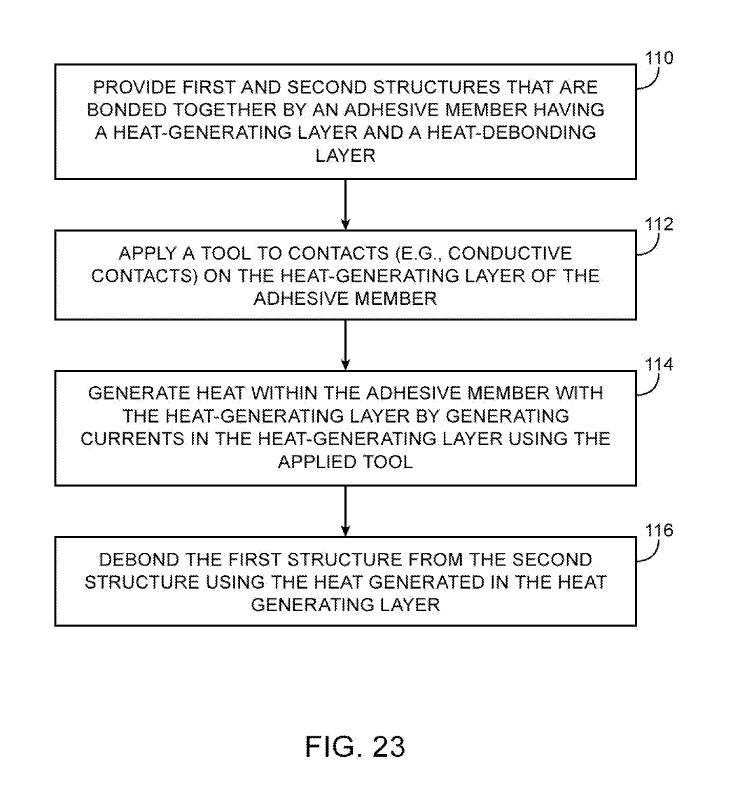

Illustrative steps that may be used in detaching structures that are bonded together with a heat-debonding adhesive member such as heat-debonding adhesive member 30 are shown in FIG. 23.

At step 110, first and second structures that are bonded together by a heat-debonding adhesive member such as heat-debonding adhesive member 30 (e.g., an adhesive member having a heat-generating layer and a heat-debonding layer) are provided.

At step 112, a tool such as debonding tool 46 of FIG. 7B is applied to contacts such as conductive contacts 42 on the heat-generating layer of the adhesive member.

At step 114, heat is generated within the adhesive member with the heat-generating layer. For example, currents may be generated (e.g., electrically driven or magnetically induced currents) in the heat generating layer using the applied tool. The currents generate heat in a conductive material in the heat-generating layer.

At step 116, the first structure is debonded from the second structure using the heat that is generated in the heat-generating layer. The generated heat may cause changes in the heat-debonding layer of the adhesive member that detach the adhesive member from one or both of the first and second structures. For example, the generated heat may expand air bubbles in a voided polymer layer that cause the adhesive member to deform and debond from the structures.

The foregoing is merely illustrative and various modifications can be made by those skilled in the art without departing from the scope and spirit of the described embodiments. The foregoing embodiments may be implemented individually or in any combination.

What is claimed is:

1. An adhesive member, comprising:
at least one adhesive layer having a bonding strength; and
a heat-generating layer attached to the at least one adhesive layer, wherein the heat-generating layer is configured to generate heat that reduces the bonding strength of the at least one adhesive layer.

2. The adhesive member defined in claim 1 wherein the at least one adhesive layer comprises a voided polymer film.

3. The adhesive member defined in claim 2 wherein the at least one adhesive layer further comprises a pressure-sensitive adhesive layer attached to the voided polymer film.

4. The adhesive member defined in claim 3 wherein the at least one adhesive layer further comprises an additional pressure-sensitive adhesive layer attached to the heat-generating layer.

5. The adhesive member defined in claim 2 wherein the at least one adhesive layer further comprises an additional voided polymer film attached to the heat-generating layer.

6. The adhesive member defined in claim 2 wherein the heat-generating layer comprises:
a carrier layer; and
a conductive layer formed on the carrier layer.

7. The adhesive member defined in claim 6 wherein the conductive layer comprises patterned conductive traces on the carrier layer.

8. The adhesive member defined in claim 6 wherein the conductive layer comprises a sheet of conductive material on the carrier layer.

9. The adhesive member defined in claim 6, further comprising an extended portion having conductive contacts.

10. The adhesive member defined in claim 6 wherein the conductive layer comprises metal wires interposed between the carrier layer and the voided polymer film.

11. An electronic device, comprising:
a first device structure;
a second device structure; and
a heat-debonding adhesive that attaches the first device structure to the second device structure, wherein the heat-debonding adhesive includes at least one heat-generating layer.

12. The electronic device defined in claim 11 wherein the heat-debonding adhesive includes a heat-debonding adhesive layer attached to the at least one heat-generating layer.

13. The electronic device defined in claim 12 wherein the first device structure comprises a battery.

14. The electronic device defined in claim 13 wherein the second device structure comprises a housing.

15. The electronic device defined in claim 14 wherein the heat-debonding adhesive includes an extended portion having conductive contacts.

16. The electronic device defined in claim 15, further comprising a gap between a portion of the housing and the battery, wherein the extended portion of the heat-debonding adhesive extends into the gap.

17. The electronic device defined in claim 12 wherein the first device structure comprises a display and wherein the second device structure comprises a housing.

18. A method of debonding a first structure from a second structure, wherein the first structure is bonded to the second structure with a heat-debonding adhesive member that is interposed between the first structure and the second structure, comprising:
generating heat within the heat-debonding adhesive member using a heat-generating layer of the heat-debonding adhesive member; and
debonding the first structure from the second structure using the generated heat.

19. The method defined in claim 18 wherein the heat-generating layer includes a conductive layer and wherein generating the heat within the heat-debonding adhesive member using the heat-generating layer of the heat-debonding adhesive member comprises generating a current in the conductive layer.

20. The method defined in claim 19 wherein generating the current in the conductive layer comprises applying a debonding tool to conductive contacts on the conductive layer.

21. The method defined in claim 18 wherein debonding the first structure from the second structure using the generated heat comprises expanding air-filled cavities in a voided polymer film in the heat-debonding adhesive member.

22. The method defined in claim 21 wherein the heat-debonding adhesive member includes a pressure-sensitive adhesive layer attached to the voided polymer film and wherein debonding the first structure from the second structure using the generated heat further comprises deforming the pressure-sensitive adhesive layer with the voided polymer film.

23. A method of attaching a first structure to a second structure, comprising:
providing the first structure;
providing the second structure;
providing an adhesive having a conductive layer and first and second pressure-sensitive adhesive layers;
pressing the first structure against the first pressure-sensitive adhesive layer; and
pressing the second structure against the second pressure-sensitive adhesive layer.

24. The method defined in claim 23 wherein the adhesive further comprises a voided polymer film attached to the first pressure-sensitive adhesive layer and wherein pressing the first structure against the first pressure-sensitive adhesive layer comprises pressing the first structure against the first pressure-sensitive adhesive layer that is attached to the voided polymer film.

25. The method defined in claim 24 wherein the first structure comprises a battery and wherein pressing the first structure against the first pressure-sensitive adhesive layer comprises attaching the adhesive to the battery.

26. The method defined in claim 25 wherein the second structure comprises an electronic device housing structure and wherein pressing the second structure against the second pressure-sensitive adhesive layer comprises attaching the battery to the electronic device housing structure using the adhesive.
